(19) United States
(12) Patent Application Publication
(10) Pub. No.: US 2016/0021788 A1
(43) Pub. Date: Jan. 21, 2016

(54) ELECTRONIC DEVICE ASSEMBLY

(71) Applicant: GENERAL ELECTRIC COMPANY, SCHENECTADY, NY (US)

(72) Inventors: Shakti Singh Chauhan, Cupertino, CA (US); James Neil Johnson, Scotia, NY (US); Brian Patrick Hoden, Huntsville, AL (US); Graham Charles Kirk, Milton Keynes (GB)

(21) Appl. No.: 14/676,241

(22) Filed: Apr. 1, 2015

Related U.S. Application Data
(60) Provisional application No. 62/025,231, filed on Jul. 16, 2014.

(51) Int. Cl. H05K 7/20; B23P 15/26

(52) U.S. Cl. CPC H05K 7/20427; B23P 15/26

(57) ABSTRACT

An electronic device assembly includes a heat sink coupled to an electronic device to dissipate the heat produced by the electronic device. A heat spreader is coupled between the electronic device and the heat sink to transfer heat from the electronic device to the heat sink. Furthermore, at least one of the electronic device, the heat spreader, and the heat sink is disposed with a disordered carbon coating.

The present application claims priority to U.S. provisional patent application Ser. No. 62/025,231 filed Jul. 16, 2014, incorporated herein by reference in its entirety.

### BACKGROUND

Embodiments of the present specification relate to thermal interfaces, and more particularly to thermal interface device.

Electronic devices often produce heat during operation that needs to be dissipated away from the electronic devices to prevent over heating of one or more components of the electronic devices. As will be appreciated, overheating of the components of the electronic devices may result in reduced reliability and/or failure of the electronic devices. Heat sinks are often used for dissipating heat away from the electronic devices. A heat sink is a passive component that is used to lower a temperature of an electronic device by dissipating heat away from the electronic device into the surrounding environment. In order for the heat sink to operate efficiently, the heat from the electronic device must be transferred to the heat sink over a thermal connection.

Typically, the electronic device includes a plurality of electronic components attached to a printed circuit board (PCB). One or more of these electronic components generate heat and may be referred to as “heat sources.” Heat from these multiple components is transferred to one or more heat sinks using thermal connections. Each component on the PCB is a particular distance from the heat sink (tolerance) and the heat must be effectively transferred across the tolerance from the component to the heat sink. Accordingly, the tolerance is often filled with a thermal connector, such as a compliant heat spreader and/or thermal interface material. The thermal connector serves to provide an efficient thermal connection by filling up micro voids present on a surface of a heat source and a surface of the heat sink. In addition, the thermal connector serves a mechanical function by providing a compliant mechanical connection between the heat source and the heat sink.

The thermal connector material needs to have electrically isolating and thermally conducting properties. Some examples of electrically isolating, thermally conducting materials include Gap pads, Gels and Adhesives. Typically these materials have lower break-down voltage and thus, require high thickness in application. However, with greater thickness they tend to have relatively poor thermal conductivity (<10 W/mK). Therefore, they provide poor thermal performance in applications that require high levels of isolation. Conversely, other commercially available electrical isolation materials like Parylene, Teflon etc. can be made quite thin because they have high dielectric strength and resistivity. However, their thermal conductivity is considerably worse (<<1 W/mK). So they don't work with high power devices, despite a smaller thickness in application.

Therefore, there is a need for even better thermal interface devices to combat improvements dielectric as well as thermal properties.

### BRIEF DESCRIPTION

In accordance with an embodiment of the present technique, an electronic device assembly is provided. The electronic device assembly includes an electronic device and a heat sink coupled to the electronic device to dissipate the heat produced by the electronic device. Furthermore, the electronic device assembly includes a heat spreader coupled between the electronic device and the heat sink to transfer heat from the electronic device to the heat sink. A disordered carbon coating is further disposed on at least one of the electronic device, the heat spreader, and the heat sink.

In accordance with another embodiment of the present technique, a method of assembling an electronic device is presented. The method includes providing disordered carbon coating on at least one of the electronic device, a heat spreader, and a heat sink. The method further includes coupling the heat sink and the electronic device to dissipate the heat produced by the electronic device. The coupling of the heat sink and the electronic device includes disposing the heat spreader between the electronic device and the heat sink to transfer heat from the electronic device to the heat sink.

### DRAWINGS

FIG. 1 is a diagrammatical representation of a conventional electronic device assembly;

FIG. 2 is a schematic diagram illustrating a coated lid for use in an electronic device assembly, in accordance with an embodiment of the present technique;

FIG. 3 is a schematic diagram illustrating an electronic device assembly, according to aspects of the present disclosure; and

FIG. 4 is a flow chart illustrating a method for assembling an electronic device, according to aspects of the present disclosure.

### DETAILED DESCRIPTION

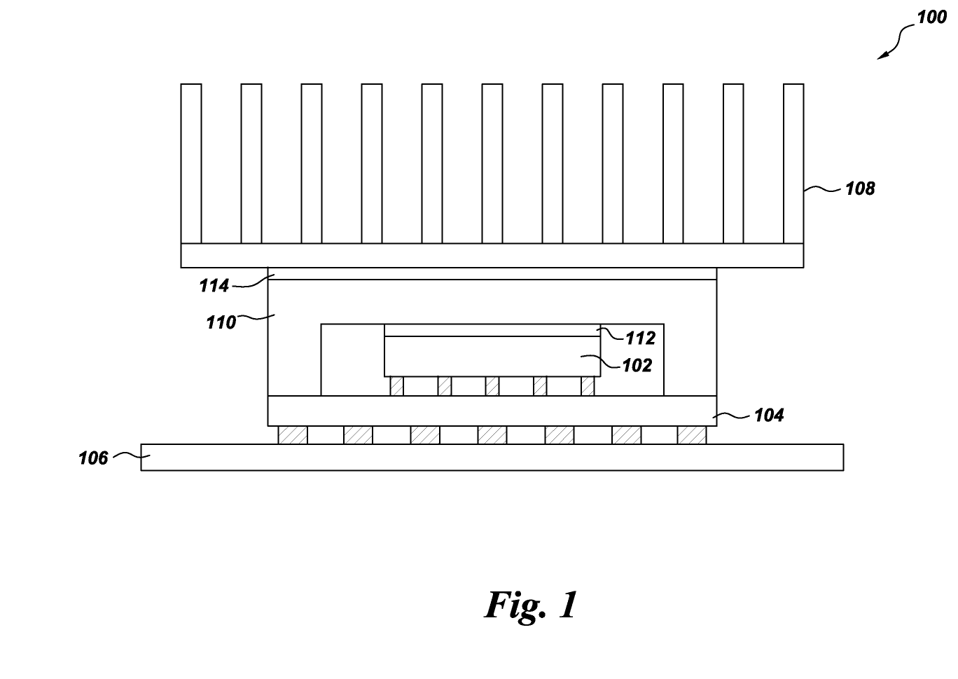

FIG. 1 illustrates a schematic view of a conventional electronic device assembly 100. In the illustrated embodiment, an electronic device such as a silicon chip 102 (also called as integrated chip) is shown. However, in other embodiments, the electronic device may be any other circuit component or a plurality of circuit components such as semiconductor switching devices, resistors and capacitors. Furthermore, in FIG. 1, only one silicon chip 102 is shown for ease of explanation, although the silicon chip 102 may be part of a larger circuit (not shown). The silicon chip 102 is mounted on a substrate 104 which is further mounted on a printed circuit board (PCB) 106.

The silicon chip 102 produces heat when energized and/or in operation. A heat sink 108 is coupled to the silicon chip 102 to dissipate the heat generated by the silicon chip into the surrounding medium. The heat sink 108 may be made from materials such as aluminum or copper alloys which have high thermal conductivity (e.g., >150 W/mk). The coupling between the heat sink 108 and the silicon chip is provided via a lid 110 (also called as heat spreader). The lid 110 is also made from high thermal conductivity material such as copper. The surfaces of silicon chip 102, heat sink 108 and lid 110 are not purely glossy or smooth. This results in reduced contact area between these components. Since a good physical contact is needed for effective heat transmission between the silicon chip 102 and heat sink 108, the lid 110 is connected to the silicon chip 102 via a thermal interface material 112. Similarly, lid 110 is also connected to the heat sink 108 by another thermal interface material 114. In one embodiment, the thermal interface materials 112 and 114 may include thermal grease which fills the contact gaps between surfaces of silicon chip 102, heat sink 108 and lid 110. Another example of thermal interface material to fill these contact gaps is a solder. However, solder is electrically conductive and also thermal grease has a lower break-down voltage which may lead to an electrical ‘leakage current’ between the silicon chip 102 and the heat sink 108. Furthermore, the electrical leakage current may be caused due to direct contact between silicon chip 102, lid 110 and heat sink 108.

Since the electrical leakage current flows in heat sink 108, the heat sink 108 generates an electrical noise which affects the electronic device (silicon chip) performance. Therefore, in some embodiments, the thermal interface material may include grease along with a gap pad (not shown). The gap pad has higher electrical resistance compared to the grease. However, the gap pad is thick and has poor thermal conductivity which affects heat transfer between the silicon chip 102 and heat sink 108.

In accordance with an embodiment of the present technique, a highly electrically resistive but highly thermally conducting coating on at least one of the electronic device, metallic heat spreader or the heat sink is provided. This results in an electrical isolating connection between the electronic device and the heat sink while providing an efficient heat transfer path.

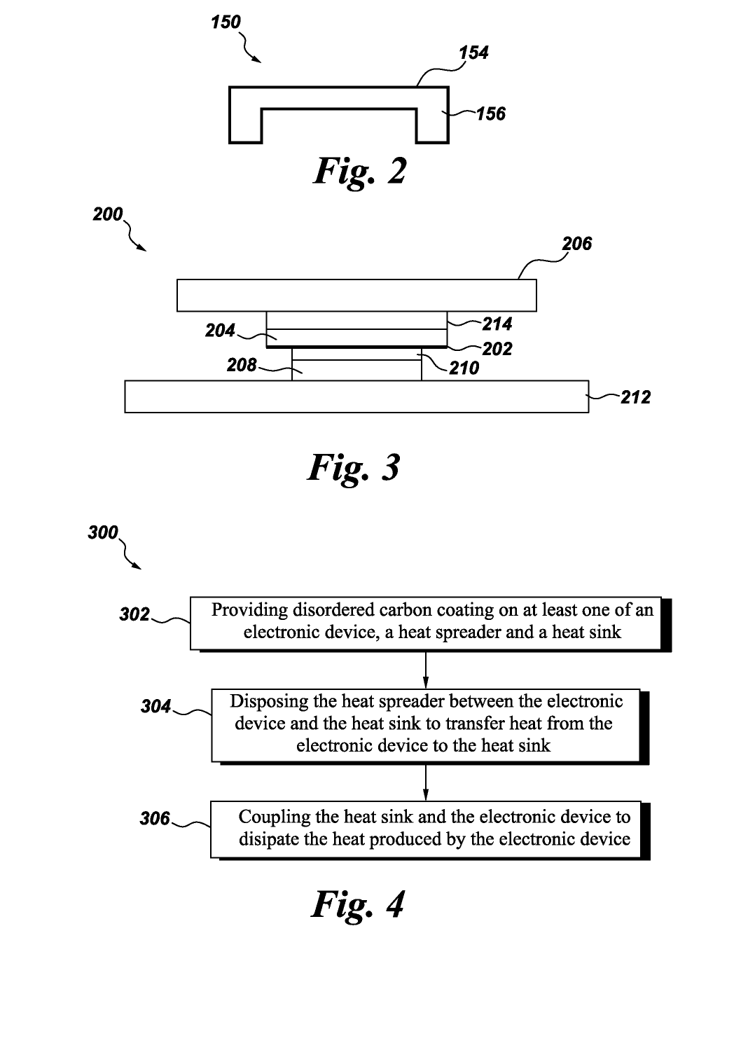

FIG. 2 shows a coated lid 150 for use in an electronic device assembly in accordance with an embodiment of the present technique. Coated lid 152 is formed by placing a coating 154 (shown by a dark black border) on a lid 156. In one embodiment, the coating may be provided by a powder coating process, a cold spray process, electrochemical coating process, electroplating or electroless plating process for example. By utilizing any of these or other coating processes, a thin layer of coating material is disposed on the surface of lid 156 and thus, coating 154 is formed. In one embodiment, the coating may be provided just on one surface which is in contact with the heat sink or the electronic device.

As discussed above, when a lid without any coating is put into the electronic device assembly, there may be a leakage current between the electronic device and the heat sink. The coating 154 blocks this leakage current. Since the coating 154 needs to block the leakage current, a material used for coating is a high electrical isolation material i.e., a material with high resistivity and/or high breakdown voltage properties. Furthermore, the coating material also has high thermal conductivity. In other words, the thermal resistance of the coating material is low. This is needed so as not to affect the heat transmission between the electronic device and the heat sink. In one embodiment, the thermal resistance of the coating material is lower e.g., in a large range of 10²-10¹⁶ Ohm-cm with high break-down voltage (e.g., 100 kV/mm) The coating material has adequate mechanical strength to survive thermal cycling on metallic, High-CTE materials. In one embodiment, the coating material may include disordered form of carbon that can be deposited on metallic substrate. The disordered form of carbon is a disordered diamond material but not diamond itself. Examples of such coatings include high SP3 content DLC coatings and Nano/Micro-crystalline Diamond coating. In one embodiment, high SP3 DLC films which have equal to or greater than 95% SP3 content is used for the coating. High SP3 DLC films have low deposition temp. (<150 C), high breakdown voltage and high thermal conductivity. In addition to the electrically isolating coating (or layer), electrically isolating thermal grease may also be utilized such that the thermal resistance can be improved further while enhancing the electrical isolation by eliminating voids or air-filled gaps between the mating surfaces.

FIG. 3 shows an electronic device assembly 200 in accordance with an embodiment of the present technique. As can be seen, a disordered Carbon Coating 202 is provided on a copper lid 204. The disordered carbon coating 202 is shown by dark line around the copper lid 204. It should also be noted that in another embodiment, the coating could also be provided on the heat sink 206 instead of the lid 204. The coated copper lid 204 is placed on to a silicon chip 208 via a first thermal interface material 210. Furthermore, the silicon chip 208 is mounted on a printed circuit board 212. The heat sink 206 is coupled to the lid 204 via a second thermal interface material 214.

It should be noted, in one embodiment, only one of the first thermal interface material 210 or the second thermal interface material 214 may be utilized. In other words, using both thermal materials 210 and 214 is not mandatory in some embodiments. As discussed earlier, the coated copper lid 204 blocks a leakage current from the silicon chip 208 to heat sink 206. Since the leakage current is blocked by the coating 202, the electrical insulation is not an issue and therefore materials such as solder and grease may be used for thermal interface materials 210 and 214. In one embodiment, gap pad may also be utilized for thermal interface material 214. It should be noted that the thickness of coating 202 is very low compared to the thickness of thermal interface materials 210 and 214.

Table 1 provides an example of thermal and insulation properties and thicknesses of various thermal interface materials and the coating. As can be seen from table 1, the first thermal interface material 210 may include materials such as grease and solder whereas the second thermal interface material 214 may include materials such as grease, solder and gap pad. Furthermore, the coating is of disordered carbon material. The electrical properties of grease thermal interface material can be insulating or conducting and that of solder can be conducting but because of the coating being insulating no leakage current can flow from silicon chip 208 to heat sink 206. The electrical property of gap pad is insulating, however, the gap pad cannot be used for 1^{st} thermal interface material 210 as it has thickness of greater than 0.3 mm. Furthermore, utilizing the insulating coating reduces the need of gap pad. The thickness of coating is in the range of 0.008 to 0.015 mm which is very low compared to the gap pad and the solder thickness of greater than 0 3 mm or even grease thickness in the range of 0.01-0.08 mm. Moreover, the thermal conductivity of the disordered carbon (>10 W/mk) is comparable to the thermal conductivity of grease (1-5 W/mk), gap pad (4-17 W/mk) and solder (17-80 W/mk).

TABLE 1

| | | | Thermal | |
|---|---|---|---|---|
| | | Thickness | Conductivity | Electrical |
| Interface | Material | (mm) | (W/mk) | Property |
| 1^{st} thermal | Grease | 0.01-0.08 | 1-5 | Insulating or |
| interface | | | | Conducting |
| material | Solder | 0.05-0.2 | 17-80 | Conducting |
| 2^{nd} thermal | Gap Pad | >0.3 | 4-17 | Insulating |
| interface | Solder | >0.3 | 17-80 | Conducting |
| material | Grease | 0.01-0.08 | 1-5 | Insulating or |
| | | | | Conducting |
| Coating | Disordered | 0.008-0.015 | >10 | Insulating |
| | Carbon | | | |

FIG. 4 shows a method 300 for assembling an electronic device in accordance with an embodiment of the present technique. In step 302, the method 300 includes providing a disordered carbon coating on at least one of an electronic device, a heat sink or a heat spreader. In one embodiment, the disordered carbon coating may be provided only on the heat spreader or on both the heat spreader and the heat sink. The disordered carbon coating may include a high electrical isolation material i.e., a material with high resistivity and/or high breakdown voltage properties. Furthermore, the coating material also has high thermal conductivity. In one embodiment, the thermal resistance of the coating material is lower e.g., in a large range of 10²-10¹⁶ Ohm-cm with high break-down voltage (e.g., 100 kV/mm) The disordered form of carbon is a diamond like carbon (DLC) material. Examples of such coatings include high SP3 content DLC coatings and Nano/Micro-crystalline Diamond coating. In one embodiment, the thickness of the coating may be in the range of 0.008-0.015 mm, whereas the thermal conductivity of the coating may be greater than 10 W/mk.

In step 304, the method includes disposing the heat spreader between the electronic device and the heat sink to transfer the heat from the electronic device to the heat sink and in step 306 the method includes coupling the heat sink and the electronic device to dissipate the heat produced by the electronic device. In one embodiment, to couple the electronic device and the heat spreader, a first thermal interface material may be disposed between them. The first thermal interface material may include grease or solder. Furthermore, coupling the heat spreader and the heat sink may include disposing a second thermal interface material between the heat sink and the heat spreader. The second thermal interface material may include solder, grease or gap pad material.

Advantages of the present technique include higher electrical and thermal performance from silicon chips used that are used in challenging (high ambient temp.) environments.

While only certain features of the invention have been illustrated and described herein, many modifications and changes will occur to those skilled in the art. It is, therefore, to be understood that the appended claims are intended to cover all such modifications and changes as fall within the true spirit of the invention.

1. An electronic device assembly comprising:
an electronic device;
a heat sink coupled to the electronic device to dissipate the heat produced by the electronic device;
a heat spreader coupled between the electronic device and the heat sink to transfer heat from the electronic device to the heat sink; and
a disordered carbon coating disposed on at least one of the electronic device, the heat spreader, and the heat sink.

2. The electronic device assembly of claim 1, wherein the electronic device includes a semiconductor chip.

3. The electronic device assembly of claim 1, wherein a material for the heat sink includes aluminum or copper alloys.

4. The electronic device assembly of claim 1, wherein a material for the heat spreader includes copper.

5. The electronic device assembly of claim 1 further comprising a first thermal interface material disposed between the electronic device and the heat spreader.

6. The electronic device assembly of claim 5, wherein the first thermal interface material includes grease or solder.

7. The electronic device assembly of claim 1 further comprising a second thermal interface material disposed between the heat spreader and the heat sink.

8. The electronic device assembly of claim 7, wherein the second thermal interface material includes grease, solder or a gap pad.

9. The electronic device assembly of claim 1, wherein the disordered carbon coating includes electrically resistive and thermally conducting coating.

10. The electronic device assembly of claim 1, wherein the disordered carbon coating includes diamond like carbon (DLC) coating, Nano/Micro-crystalline Diamond coating, or disordered diamond.

11. The electronic device assembly of claim 10, wherein the DLC coating includes a SP3 content equal to higher than 95%.

12. The electronic device assembly of claim 1, wherein the coating is disposed on one side or both sides of the heat spreader.

13. A method of assembling an electronic device, comprising:
providing disordered carbon coating on at least one of the electronic device, a heat spreader, and a heat sink;
coupling the heat sink and the electronic device to dissipate the heat produced by the electronic device;
wherein coupling the heat sink and the electronic device comprises disposing the heat spreader between the electronic device and the heat sink to transfer heat from the electronic device to the heat sink.

14. The method of claim 13, wherein providing disordered carbon coating includes providing diamond like carbon (DLC) coating or Nano/Micro-crystalline Diamond coating or disordered diamond coating.

15. The method of claim 14, wherein the DLC coating includes a SP3 content equal to higher than 95%.

16. The method of claim 13, wherein providing disordered carbon coating includes disposing the coating on one side or both sides of the heat spreader.

17. The method of claim 13, wherein disposing the heat spreader between the electronic device and the heat sink comprises providing a first thermal interface material between the electronic device and the heat spreader.

18. The method of claim 17, wherein the first thermal interface material includes grease or solder.

19. The method of claim 13, wherein disposing the heat spreader between the electronic device and the heat sink comprises providing a second thermal interface material disposed between the heat spreader and the heat sink.

20. The method of claim 19, wherein the second thermal interface material includes grease, solder or a gap pad.
